(19) United States
(12) Patent Application Publication
(10) Pub. No.: US 2026/0019092 A1
(43) Pub. Date: Jan. 15, 2026

(54) HYBRID LATTICE FILTER WITH ACOUSTIC BALUN

(71) Applicant: Qorvo US, Inc., Greensboro, NC (US)

(72) Inventors: Yazid Yusuf, Orlando, FL (US); Marcus Granger-Jones, Scotts Valley, CA (US)

(21) Appl. No.: 19/206,773

(22) Filed: May 13, 2025

Related U.S. Application Data
(60) Provisional application No. 63/668,826, filed on Jul. 9, 2024.

(51) Int. Cl. H04B 1/00; H01P 5/10; H03H 7/42; H04B 1/40

(52) U.S. Cl. CPC H04B 1/0003; H01P 5/10; H03H 7/42; H04B 1/40

(57) ABSTRACT

Hybrid lattice filters with acoustic baluns are disclosed. In one aspect, a hybrid lattice filter may be formed using acoustic elements. The hybrid lattice filter may operate with acoustic baluns such as coupled resonator filters (CRF) or stacked crystal filters (SCF). To achieve the desired common mode rejection, an additional rejection or low common mode intermediate impedance network may be supplied between the acoustic balun and the hybrid lattice filter. By combining the acoustic balun with the low common-mode intermediate impedance network and the hybrid lattice filter, a passband filter with a desired bandwidth may be created.

### PRIORITY APPLICATION

The present application claims priority to U.S. Provisional Patent Application Ser. No. 63/668,826, filed Jul. 9, 2024, and entitled “HYBRID LATTICE FILTER WITH ACOUSTIC BALUN,” which is incorporated herein by reference in its entirety

### BACKGROUND

### I. Field of the Disclosure

The technology of the disclosure relates generally to filters for use in wireless communication devices and, more particularly, to acoustic filters.

### II. Background

Communication devices abound in modern society, and more particularly, mobile communication devices have become increasingly common. The prevalence of these mobile communication devices is driven in part by the many functions that are now enabled on such devices. Increased processing capabilities in such devices means that mobile communication devices have evolved from pure communication tools into sophisticated mobile entertainment centers, thus enabling enhanced user experiences. With the advent of the myriad functions available to such devices, there has been increased pressure to find ways to provide additional bandwidth through which to send and receive data to such mobile devices. The wireless standards associated with such mobile communication continue to evolve, providing larger frequency ranges over which data may be sent and received. Providing a filter that assists in reducing signal noise for transceivers that are operating in these frequency ranges provides room for innovation.

### SUMMARY

Aspects disclosed in the detailed description include a hybrid lattice filter with an acoustic balun. In particular, a hybrid lattice filter may be formed using acoustic elements. The hybrid lattice filter may operate with an acoustic balun, such as coupled resonator filters (CRF) or stacked crystal filters (SCF). To achieve the desired common-mode rejection, an additional low common-mode intermediate impedance network may be positioned between the acoustic balun and the hybrid lattice filter. By combining the acoustic balun with the low common-mode intermediate impedance network and the hybrid lattice filter, a passband filter with a desired bandwidth may be created.

In this regard, in one aspect, a filter is disclosed. The filter includes an acoustic balun configured to transform a balanced signal to an unbalanced signal, a hybrid lattice filter comprising two lattice impedance elements, and an intermediate impedance network positioned between the acoustic balun and the hybrid lattice filter.

In another aspect, a method of filtering a signal is disclosed. The method includes turning a balanced signal into an unbalanced signal using an acoustic balun and using a low common mode impedance intermediate network and a hybrid lattice filter on the balanced signal.

In another aspect, a communication device is disclosed. The communication device includes a transceiver chain comprising a power amplifier and a filter comprising an acoustic balun configured to transform a balanced signal into an unbalanced signal. The communication device also includes a hybrid lattice filter comprising two lattice impedance elements and an intermediate impedance network positioned between the acoustic balun and the hybrid lattice filter.

### BRIEF DESCRIPTION OF THE DRAWINGS

FIG. 1A is a mixed circuit-block diagram of a hybrid lattice topology with an ideal transformer balun;

FIG. 1B is the same mixed circuit-block diagram of FIG. 1A, but reversed to align with the later figures of the present disclosure;

FIG. 2A is a mixed circuit-side elevational view of a first coupled resonator filter (CRF) balun that may be used with aspects of the present disclosure;

FIG. 2B is a mixed circuit-side elevational view of a second CRF balun that may be used with aspects of the present disclosure;

FIG. 2C is a mixed circuit-side elevational view of a stacked crystal filter (SCF) balun that may be used with aspects of the present disclosure;

FIG. 3 is a block diagram of a hybrid lattice filter with an acoustic balun and intermediate impedance network to provide a low common-mode impedance according to aspects of the present disclosure;

FIG. 4A is a mixed circuit-side elevational view of the balun of FIG. 2B with a first intermediate impedance network;

FIG. 4B is a mixed circuit-side elevational view of the balun of FIG. 2B with a second intermediate impedance network;

FIG. 4C is a mixed circuit-side elevational view of the balun of FIG. 2B with both the first and second intermediate impedance networks of FIGS. 4A & 4B;

FIG. 5A is a mixed circuit-side-block diagram of a hybrid lattice filter with the combined intermediate impedance network and the balun of FIG. 2B;

FIG. 5B is a graph of a frequency response for the filter of FIG. 5A compared to a frequency response without the intermediate impedance network;

FIG. 5C is a mixed circuit-side elevational diagram of the filter of FIG. 5A;

FIG. 6 is a mixed circuit-side elevational view of the balun of FIG. 2C with a first intermediate impedance network;

FIG. 7A is a mixed circuit-side-block diagram of a hybrid lattice filter with the combined intermediate impedance network and the balun of FIG. 2C;

FIG. 7B is a graph of a frequency response for the filter of FIG. 7A compared to a frequency response without the intermediate impedance network;

FIG. 8 is a flowchart illustrating an exemplary process for filtering according to aspects of the present disclosure; and

FIG. 9 is a block diagram of a communication device, which may include the hybrid lattice filter with acoustic baluns according to the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that although the terms first, second, etc. may be used herein to describe various elements, these elements should not be limited by these terms. These terms are only used to distinguish one element from another. For example, a first element could be termed a second element, and similarly, a second element could be termed a first element without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element, or intervening elements may also be present. In contrast, when an element is referred to as being “directly on” or extending “directly onto” another element, no intervening elements are present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, no intervening elements are present. It will also be understood that when an element is referred to as being “connected” or “coupled” to another element, it can be directly connected or coupled to the other element, or intervening elements may be present. In contrast, when an element is referred to as being “directly connected” or “directly coupled” to another element, no intervening elements are present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

In keeping with the above admonition about definitions, the present disclosure uses transceiver in a broad manner. Current industry literature uses “transceiver” in two ways. The first way uses transceiver broadly to refer to a plurality of circuits that send and receive signals. Exemplary circuits may include a baseband processor, an up/down conversion circuit, filters, amplifiers, couplers, and the like coupled to one or more antennas. A second way, used by some authors in the industry literature, refers to a circuit positioned between a baseband processor and a power amplifier circuit as a transceiver. This intermediate circuit may include the up/down conversion circuits, mixers, oscillators, filters, and the like but generally does not include the power amplifiers. As used herein, the term transceiver is used in the first sense. Where relevant to distinguish between the two definitions, the terms “transceiver chain” and “transceiver circuit” are used respectively.

Additionally, to the extent that the term “approximately” is used in the claims, it is herein defined to be within five percent (5%).

Aspects disclosed in the detailed description include a hybrid lattice filter with an acoustic balun. In particular, a hybrid lattice filter may be formed using acoustic elements. The hybrid lattice filter may operate with an acoustic balun such as a coupled resonator filters (CRF) or stacked crystal filters (SCF). To achieve the desired common mode rejection, an additional low common-mode intermediate impedance network may be positioned between the acoustic balun and the hybrid lattice filter. By combining the acoustic balun with the low common-mode intermediate impedance network and the hybrid lattice filter, a passband filter with a desired bandwidth may be created.

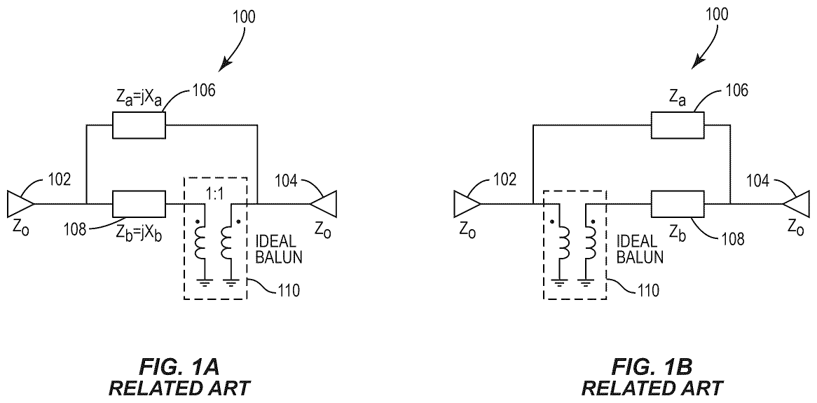

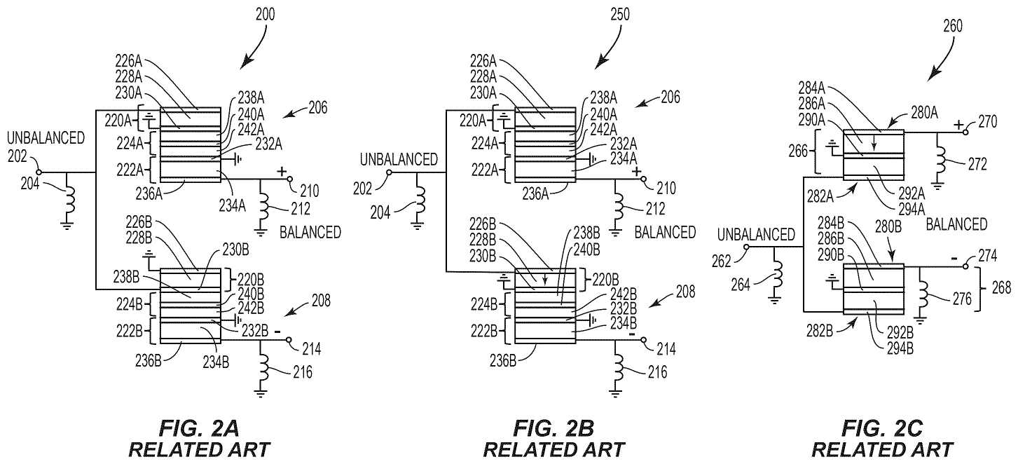

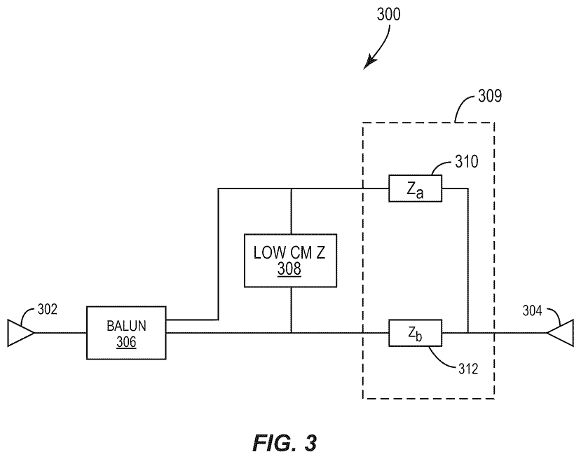

Before addressing aspects of the present disclosure, a brief overview of hybrid lattice filters is provided with reference to FIGS. 1A & 1B; a discussion of acoustic baluns is provided with reference to FIGS. 2A-2C. A discussion of aspects of the present disclosure begins below with reference to FIG. 3.

The emerging trends in wireless communication are at frequency ranges having signal bandwidths that are relatively large. Lattice and hybrid lattice filters are attractive because of the generality of filtering functions that may be achieved. Using these topologies, relatively wide bandwidth bandpass acoustic resonator filters can be realized since these topologies are naturally able to compensate for static capacitances of acoustic resonators and circumvent the bandwidth limitations of ladder filters due to the limited electromechanical coupling (k2E). Being balanced structures, lattice and hybrid lattice topologies may require the usage of a balun for unbalanced operation.

In this regard, FIGS. 1A & 1B illustrate a filter 100 having a hybrid lattice topology utilizing an ideal transformer balun. FIGS. 1A & 1B are mirror images of one another to show that the direction the signals pass through does not change the filter function to which they are subjected. Thus, a first input/output (I/O) node 102 has an impedance of Zₒ. Similarly, a second I/O node 104 also has an impedance of Zₒ. A first lattice impedance element 106 has an impedance of Zₐ. Zₐ may be equal to jXₐ. A second lattice impedance element 108 has an impedance of Z_{b}. An ideal transformer balun 110 provides unbalanced operation for the balanced lattice structure. The lattice impedance elements 106 and 108 may consist of any combination of capacitors, inductors, and acoustic resonators.

Z_{b} may be equal to jX_{b}. When Xₐ=X_{b}, the filter 100 will be a stopband filter. Of greater interest for the present disclosure, when Xₐ=−X_{b}, the filter 100 will be a passband filter.

Commonly used coupled inductor baluns may approach a theoretical ideal, such as ideal transformer balun 110, but they have several disadvantages when implemented. One key disadvantage of their use in mobile communication devices is their size. Furthermore, low balun loss requires high mutual coupling between inductor windings, and this coupling is limited by design rules of existing laminate technologies and the minimum allowable spacing between traces. Parasitic capacitance between inductor windings results in reduced common-mode rejection, which limits the rejection available. While shielding can be used to improve common-mode rejection, this shielding reduces the mutual coupling of the coils since the separation between the primary and secondary coils needs to be increased to accommodate the shielding traces.

Aspects of the present disclosure rely on an acoustic balun in place of the theoretical ideal or the coupled inductor baluns. Baluns based on acoustic resonators are attractive alternatives to coupled inductor baluns because of their smaller size and additional rejection provided, given their inherent filtering function.

To assist the reader, a discussion of some acoustic baluns is provided with reference to FIGS. 2A-2C. In this regard, FIG. 2A illustrates a CRF balun 200 with an unbalanced node 202 that is coupled to a shunt inductor 204, a first balun branch 206, and a second balun branch 208. The first balun branch 206 is coupled to a first balanced node 210 and a shunt inductor 212. Similarly, the second balun branch 208 is coupled to a second balance node 214 and a shunt inductor 216.

Each of the first and second balun branches 206 and 208 are formed from paired resonators separated by acoustic impedance layers. In particular, the first balun branch 206 has a first resonator 220A and a second resonator 222A separated by coupling layers 224A. The first resonator 220A has a top electrode 226A, a piezoelectric layer 228A, and a bottom electrode 230A. The second resonator 222A likewise has a top electrode 232A, a piezoelectric layer 234A, and a bottom electrode 236A. The coupling layers 224A include a top low acoustic impedance layer 238A, a middle high acoustic impedance layer 240A, and a bottom low acoustic impedance layer 242A. The bottom electrode 230A and the top electrode 232A are both coupled to ground. The top electrode 226A is coupled to the unbalanced node 202, and the bottom electrode 236A is coupled to the first balanced node 210.

The second balun branch 208 is substantially identical. In particular, the second balun branch 208 has a first resonator 220B, and a second resonator 222B separated by coupling layers 224B. As shown in FIG. 2A, the first resonator 220B has a top electrode 226B, a piezoelectric layer 228B, and a bottom electrode 230B. The second resonator 222B likewise has a top electrode 232B, a piezoelectric layer 234B, and a bottom electrode 236B. The coupling layers 224B include a top low acoustic impedance layer 238B, a middle high acoustic impedance layer 240B, and a bottom low acoustic impedance layer 242B. The top electrode 226B and the top electrode 232B are both coupled to ground. The bottom electrode 230B is coupled to the unbalanced node 202, and the bottom electrode 236B is coupled to the second balanced node 214.

A 180-degree phase shift between the first balun branch 206 and the second balun branch 208 is effectuated by the interchanged connection to the top electrode 226A in the first resonator 220A compared to the connection to the bottom electrode 230B in the second resonator 222B.

Instead of using the different interconnections, one of the resonators may have an inverted polarization of piezoelectric material, as better illustrated in FIG. 2B. In particular, in the CRF balun 250, one of the piezoelectric layers 228A, 234A, 228B, or 234B is inverted (layer 234A is shown as inverted). In other regards, the structures are nearly identical, although the unbalanced node couples to both top electrodes 226A, 226B instead of one top and one bottom as in CRF balun 200.

While CRF baluns have two ways to introduce the 180-degree phase shift, SCF balun 260 has to rely on an inverted polarization, as shown in FIG. 2C. In this regard, the SCF balun 260 has an unbalanced node 262 that is coupled to a shunt inductor 264, a first balun branch 266, and a second balun branch 268. The first balun branch 266 is coupled to a first balanced node 270 and a shunt inductor 272. Similarly, the second balun branch 268 is coupled to a second balance node 274 and a shunt inductor 276.

Each of the first and second balun branches 266 and 268 is formed from paired resonators separated by a shared middle electrode. In particular, the first balun branch 266 has a first resonator 280A and a second resonator 282A. The first resonator 280A has a top electrode 284A, a piezoelectric layer 286A, and a bottom electrode 290A. The second resonator 282A uses the bottom electrode 290A as its top electrode and also includes a piezoelectric layer 292A, and a bottom electrode 294A. The bottom electrode 290A is coupled to ground. The top electrode 284A is coupled to the first balanced node 270, and the bottom electrode 294A is coupled to the unbalanced node 262.

The second balun branch 268 has a first resonator 280B and a second resonator 282B. The first resonator 280B has a top electrode 284B, a piezoelectric layer 286B and a bottom electrode 290B. The second resonator 282B uses the bottom electrode 290B as its top electrode and also includes a piezoelectric layer 292B, and a bottom electrode 294B. The bottom electrode 290B is coupled to ground. The top electrode 284B is coupled to the second balanced node 274, and the bottom electrode 294B is coupled to the unbalanced node 262.

As noted, one of the piezoelectric layers 286A, 286B, 292A, or 292B has inverted polarity (layer 286A shown).

CRF and SCF baluns exhibit high common-mode rejection. However, the acoustic baluns do not have the desired low-common mode impedance for use with hybrid lattice filters and may have notches in the desired passband frequency range.

Aspects of the present disclosure add an intermediate impedance network between the acoustic balun and the hybrid lattice filter as illustrated in FIG. 3. More specifically, a filter 300 is formed between an I/O node 302 and a second I/O node 304 by coupling the unbalanced side of acoustic balun 306 to the I/O node 302. An intermediate impedance network 308 is connected across the balanced ends of balun 306. A hybrid lattice filter 309 connects to the balanced ends of the balun. More specifically, the first lattice impedance element 310 connects to one balanced end and second lattice impedance element 312 connects to the second balanced end. The lattice impedance elements 310, 312 also connect to the second I/O node 304 of the filter 300. The acoustic balun 306 may be any of the acoustic baluns 200, 250, or 260 described above.

The intermediate impedance network 308 has low common-mode impedance to assist in reducing the notches that may occur in a filter formed without the intermediate impedance network 308.

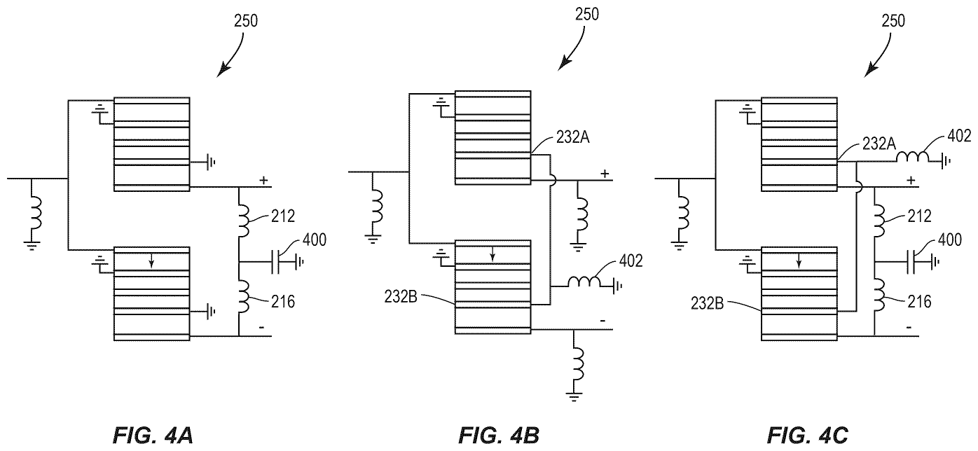

FIGS. 4A-4C illustrate exemplary intermediate impedance networks used with the CRF balun 250 of FIG. 2B. It should be appreciated that these impedance networks may work with any of the baluns.

FIG. 4A illustrates the CRF balun 250 with an added capacitor 400 that couples the shunt inductors 212, 216 to ground. The capacitor 400, in combination with the shunt inductors 212 and 216, form the intermediate impedance network 308 exhibiting low common mode impedance. FIG. 4B illustrates the CRF balun 250 with an added inductor 402 that couples top electrodes 232A, 232B to ground. In this case, the static capacitances of the bottom resonators in the two balun branches, along with the added shunt inductor 402, form the intermediate impedance network 308 exhibiting low common mode impedance. FIG. 4C illustrates the CRF balun 250 with both the capacitor 400 and the inductor 402 added.

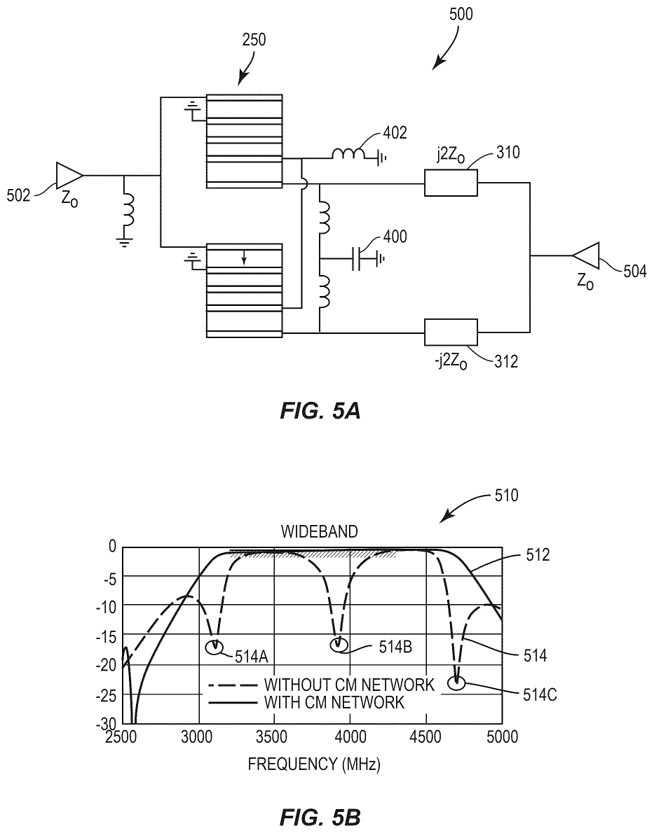

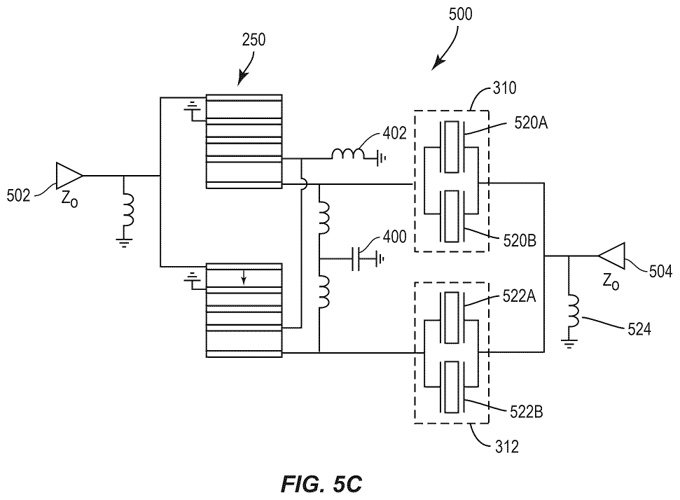

When the structure of FIG. 4C is substituted back into the filter 300, the resulting filter 500 is the result, and illustrated in FIG. 5A. In particular, an I/O node 502 couples to the CRF balun 250. Intermediate impedance network formed from the capacitor 400 and the inductor 402 is placed between the CRF balun 250 and hybrid lattice impedance elements 310, 312. A second I/O node 504 couples the lattice impedance elements 310, 312.

With the hybrid lattice impedance elements configured to passband conditions (jXb=−jXa), the filter 500 has a desirable frequency response 512, as shown in graph 510 of FIG. 5B especially as compared to the frequency response 514 that results if the intermediate impedance network is not used. That is, notches 514A-514C may exist in the frequency response, indicating less than desired performance at those frequencies.

A more complete version of the filter 500 is provided with reference to FIG. 5C, where the lattice impedance elements 310, 312 are expanded to show acoustic resonators 520A, 520B and acoustic resonators 522A, 522B respectively. A shunt inductor 524 is added to complete the lattice impedance elements.

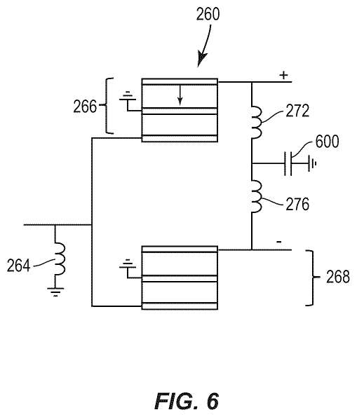

FIG. 6 illustrates the SCF balun 260 with an intermediate impedance network formed from a capacitor 600 coupling shunt inductors 272, 276 to ground. Again, it should be appreciated that other low common-mode impedance networks could be used.

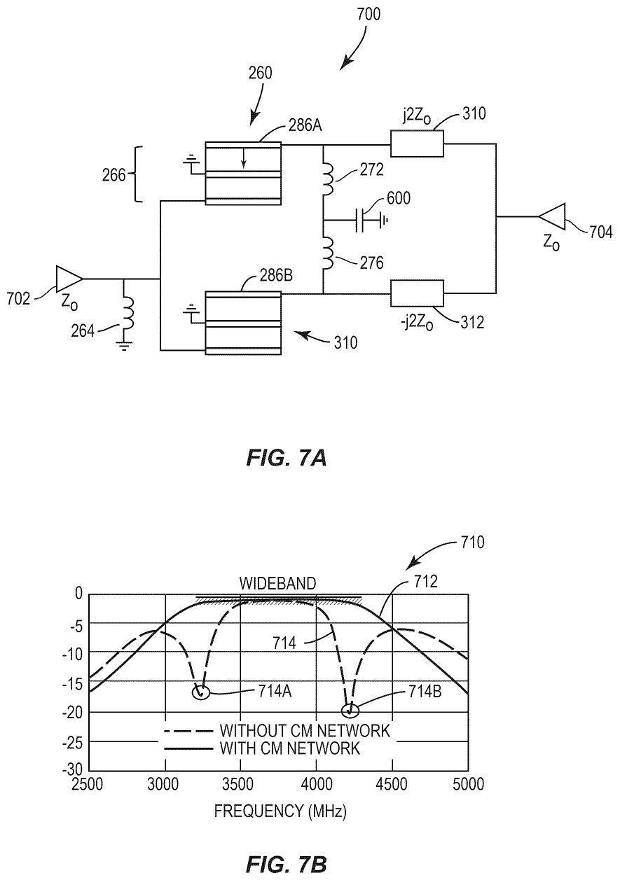

FIGS. 7A & 7B illustrate the SCF balun 260 substituted back into the filter 300 to provide a filter 700. In particular, an I/O node 702 couples to the SCF balun 260. Intermediate impedance network formed from the capacitor 600 is placed between the SCF balun 260 and hybrid lattice impedance elements 310, 312. A second I/O node 704 couples the lattice impedance elements 310, 312.

Configured to passband conditions (jXb=−jXa), the filter 700 has a desirable frequency response 712 as shown in graph 710 of FIG. 7B, especially as compared to the frequency response 714 that results if the intermediate impedance network is not used. That is, notches 714A-714B may exist in the frequency response, indicating less than desired performance at those frequencies.

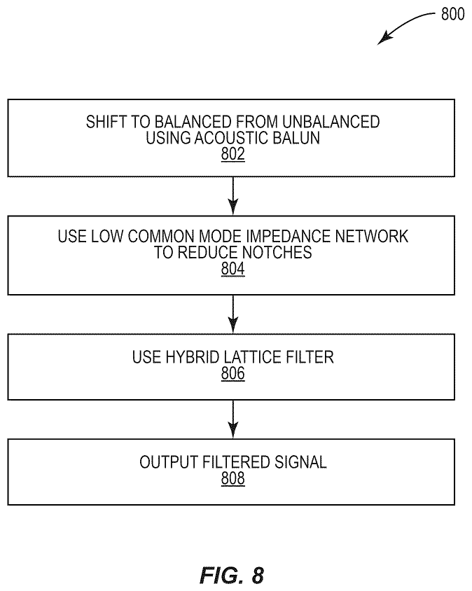

FIG. 8 illustrates a process 800 for using the hybrid lattice filters with acoustic baluns of the present disclosure. In particular, the process 800 begins by shifting to a balanced signal from an unbalanced signal using an acoustic balun (block 802). Then, a low common mode impedance network is used to reduce notches (block 804) from the acoustic balun. The hybrid lattice filter is then used (block 806) to complete the filtering and recombine to an unbalanced signal. The filter then outputs the filtered signal (block 808).

The hybrid lattice filter with acoustic balun according to aspects disclosed herein, may be provided in or integrated into any processor-based device that needs such a wideband filter. The expected use is a mobile terminal such as a cell phone, but the present disclosure is not so limited. Other examples, without limitation, include a set-top box, an entertainment unit, a navigation device, a communications device, a fixed location data unit, a mobile location data unit, a global positioning system (GPS) device, a mobile phone, a cellular phone, a smartphone, a session initiation protocol (SIP) phone, a tablet, a phablet, a server, a computer, a portable computer, a mobile computing device, a wearable computing device (e.g., a smartwatch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

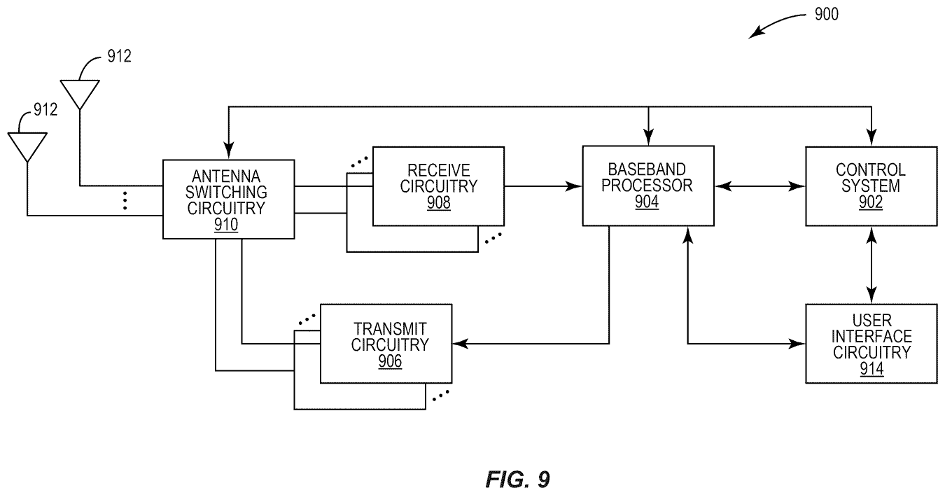

FIG. 9 is a schematic diagram of an exemplary communication device 900 wherein the filters using hybrid lattices with acoustic baluns can be provided. It is expected that such filters will be in the transmission chains as wireless signals are conditioned for transmission, but other locations may also use the present disclosure. Herein, the communication device 900 can be any type of communication device, such as those listed above as well as access points, base stations (e.g., eNB or gNB), and any other type of wireless communication devices that support wireless communications, such as cellular, wireless local area network (WLAN), Bluetooth, Ultra-wideband (UWB), and near field communications.

More particularly, the communication device 900 will generally include a control system 902, a baseband processor 904, transmit circuitry 906, receive circuitry 908, antenna switching circuitry 910, multiple antennas 912, and user interface circuitry 914. In a non-limiting example, the control system 902 can be a field-programmable gate array (FPGA) or an application-specific integrated circuit (ASIC), as an example. In this regard, the control system 902 can include at least a microprocessor(s), an embedded memory circuit(s), and a communication bus interface(s). The receive circuitry 908 receives radio frequency signals via the antennas 912 and through the antenna switching circuitry 910 from one or more base stations. A low noise amplifier and a filter of the receive circuitry 908 cooperate to amplify and remove broadband interference from the received signal for processing. Downconversion and digitization circuitry (not shown) will then downconvert the filtered, received signal to an intermediate or baseband frequency signal, which is then digitized into one or more digital streams using an analog-to-digital converter(s) (ADC).

The baseband processor 904 processes the digitized received signal to extract the information or data bits conveyed in the received signal. This processing typically comprises demodulation, decoding, and error correction operations. The baseband processor 904 is generally implemented in one or more digital signal processors (DSPs) and ASICs.

For transmission, the baseband processor 904 receives digitized data, which may represent voice, data, or control information, from the control system 902, which it encodes for transmission. The encoded data is output to the transmit circuitry 906, where a digital-to-analog converter(s) (DAC) converts the digitally encoded data into an analog signal, and a modulator modulates the analog signal onto a carrier signal that is at a desired transmit frequency or frequencies. A power amplifier will amplify the modulated carrier signal to a level appropriate for transmission and deliver the modulated carrier signal to the antennas 912 through filters such as the filters disclosed herein and through the antenna switching circuitry 910. The multiple antennas 912 and the replicated transmit and receive circuitries 906, 908 may provide spatial diversity. Modulation and processing details will be understood by those skilled in the art.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications, as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein but is to be accorded the widest scope consistent with the principles and novel features disclosed herein.

What is claimed is:

1. A filter comprising:
an acoustic balun configured to transform a balanced signal to an unbalanced signal;
a hybrid lattice filter comprising two lattice impedance elements; and
an intermediate impedance network positioned between the acoustic balun and the hybrid lattice filter.

2. The filter of claim 1, wherein the acoustic balun comprises a coupled resonator filter (CRF).

3. The filter of claim 1, wherein the acoustic balun comprises two balun branches.

4. The filter of claim 1, wherein the acoustic balun comprises a stacked crystal filter (SCF).

5. The filter of claim 1, wherein the intermediate impedance network comprises a capacitor coupled to ground.

6. The filter of claim 3, wherein the intermediate impedance network comprises an inductor coupled to ground on one end, and on its other end, the inductor couples to a top electrode of a first balun branch and a second top electrode of a second balun branch.

7. The filter of claim 6, wherein the intermediate impedance network further comprises a capacitor coupled to ground.

8. The filter of claim 1, wherein the hybrid lattice filter comprises a first lattice impedance element comprising two parallel acoustic resonators.

9. The filter of claim 8, wherein the hybrid lattice filter further comprises a second lattice impedance element comprising a second two parallel acoustic resonators.

10. The filter of claim 1, wherein the acoustic balun comprises an inverted polarity piezoelectric material layer.

11. The filter of claim 1, wherein the intermediate impedance network comprises a low common-mode impedance.

12. A method of filtering a signal comprising:
turning an unbalanced signal into a balanced signal using an acoustic balun;
using a low common-mode intermediate impedance network on the balanced signal; and
using a hybrid lattice filter on the balanced signal.

13. The method of claim 12, further comprising recombining the balanced signal to an unbalanced signal.

14. The method of claim 12, wherein using the low common mode intermediate impedance network comprises using one of an inductor or a capacitor.

15. The method of claim 12, wherein using the low common mode intermediate impedance network comprises using both an inductor and a capacitor.

16. The method of claim 12, wherein using the acoustic balun comprises using a coupled resonator filter (CRF) balun.

17. The method of claim 12, wherein using the acoustic balun comprises using a stacked crystal filter (SCF) balun.

18. A communication device comprising:
a transceiver chain comprising:
a power amplifier; and
a filter comprising:
an acoustic balun configured to transform a balanced signal to an unbalanced signal;
a hybrid lattice filter comprising two lattice impedance elements; and
an intermediate impedance network positioned between the acoustic balun and the hybrid lattice filter.

19. The communication device of claim 18, wherein the acoustic balun comprises a coupled resonator filter (CRF).

20. The communication device of claim 18, wherein the acoustic balun comprises a stacked crystal filter (SCF).
